(19) United States
(12) Patent Application Publication
(10) Pub. No.: US 2008/0283822 A1
(43) Pub. Date: Nov. 20, 2008

(54) SEMICONDUCTOR LIGHT EMITTING DEVICE

(75) Inventor: Keiichi YUI, Yamanashi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: EUDYNA DEVICES INC., Nakakoma-gun (JP)

(21) Appl. No.: 12/122,298

(22) Filed: May 16, 2008

(30) Foreign Application Priority Data
May 17, 2007 (JP) 2007-132193

(51) Int. Cl. H01L 33/00

(52) U.S. Cl. 257/13; 257/E33.008

(57) ABSTRACT

A semiconductor light emitting device includes a substrate and a quantum well active layer. The quantum well active layer has a plurality of barrier layers made of GaN-based semiconductor and a well layer made of GaN-based semiconductor sandwiched between the barrier layers and has polarized charge between the barrier layer and the well layer caused by piezo polarization. The well layer has a composition modulation so that a band gap is minimum at an interface between the well layer and one of the barrier layers more far from the substrate than the other.

### BACKGROUND OF THE INVENTION

1. Field of the Invention

The present invention relates a semiconductor light emitting device, and in particular, relates to a semiconductor light emitting device having a quantum well active layer.

2. Description of the Related Art

A semiconductor light emitting device such as LED (Light Emitting Diode) or LD (Laser Diode) having a GaN (gallium nitride)-based semiconductor is being used as a light emitting device for short wavelength.

Japanese Patent Application Publication No. 2005-056973 (hereinafter referred to as Document 1) discloses a semiconductor light emitting device having a MQW (Multi Quantum Well) active layer made of GaN-based semiconductor. As shown in FIG. 5 of Document 1, an N-type cladding layer, a MQW active layer, and a P-type cladding layer are laminated on a substrate. FIG. 1A through FIG. 2B illustrate In composition ratio and energy of a well layer 30 and a barrier layer 32 of the semiconductor light emitting device disclosed in Document 1 with respect to a normal line direction ([0001] direction) of the substrate, the well layer 30 being one layer of the MQW active layer, the barrier layer 32 being positioned at both sides of the well layer. The MQW active layer has a plurality of barrier layers 32 and the well layer 30 that is sandwiched with the barrier layers 32. It is known that the GaN-based semiconductor is polarized largely. Therefore, polarized charge caused by piezo polarization is generated when a-axis lattice constant of the barrier layer 32 is different from that of the well layer 30, the barrier layer 32 and the well layer 30 being laminated in [0001] direction, for example. The polarized charge is generated, at least when the a-axis lattice constants are different from each other.

The a-axis lattice constant of the well layer 30 is larger than that of the barrier layer 32 when the barrier layer 32 is made of GaN and the well layer 30 is made of InGaN as shown in FIG. 1A, in a case where the normal line direction of the substrate (that is a lamination direction) is [0001] direction (c-axis direction). This results in a formation of a negative polarized charge on the substrate side of the well layer 30 and a formation of a positive polarized charge on the opposite side of the well layer 30.

The polarized charge causes an increase of the energy of a conduction band and a valence band in the well layer 30 on the substrate side and a decrease of the energy of a conduction band and a valence band in the well layer 30 on the opposite side to the substrate. Therefore, an electron is in the well layer 30 on the opposite side to the substrate, and a hole is in the well layer 30 on the substrate side, with reference to a wave function in FIG. 1B. A recombination rate between the electron and the hole is reduced and a light-emitting efficiency is reduced because the electron and the hole are spatially separated from each other.

As shown in FIG. 2A, the composition ratio of In (indium) is relatively large on the substrate side of the well layer 30, and is relatively low on the opposite side of the wall layer 30. This results in a decrease of an energy band gap on the substrate side of the well layer 30 and an increase of the energy band gap on the opposite side of the well layer 30, as shown in FIG. 2B. Therefore, the electron and the hole are on the substrate side, and the spatial separation of the electron and the hole is restrained. The GaN-based semiconductor is, for example, GaN, AlN, InN, InGaN that is a mixed crystal between the GaN and InN, AlGaN that is a mixed crystal between GaN and AlN, AlInGaN or the like.

However, the light-emitting efficiency is not sufficient even if the MQW active layer disclosed in Document 1 is used.

### SUMMARY OF THE INVENTION

The present invention has been made in view of the above circumstances and improves the light-emitting efficiency.

According to an aspect of the present invention, there is provided a semiconductor light emitting device including a substrate and a quantum well active layer. The quantum well active layer has a plurality of barrier layers made of GaN-based semiconductor and a well layer made of GaN-based semiconductor sandwiched between the barrier layers and has polarized charge between the barrier layer and the well layer caused by piezo polarization. The well layer has a composition modulation so that a band gap is minimum at an interface between the well layer and one of the barrier layers more far from the substrate than the other. With the structure, positional separation between an electron and a hole is restrained. And light-emitting efficiency is improved.

### BRIEF DESCRIPTION OF THE DRAWINGS

Other objects, features and advantages of the present invention will become more apparent from the following detailed description when read in conjunction with the accompanying drawings, in which:

FIG. 1A and FIG. 1B illustrate In composition and energy in a well layer of a LED disclosed in Document 1;

FIG. 2A and FIG. 2B illustrate In composition ratio and energy in a well layer of another LED disclosed in Document 1;

FIG. 3A and FIG. 3B illustrate a principle of the present invention and illustrate In composition ratio and energy in the well layer of the LED;

FIG. 4 illustrates a cross sectional view of a LED in accordance with a first embodiment;

FIG. 5A through FIG. 5C illustrate In composition ratio of a well layer of a sample A, a sample B and a sample C respectively;

FIG. 6 illustrates light emission intensity of the samples A through C;

FIG. 7 illustrates light emission intensity of the samples A, C and D with respect to electrical current;

FIG. 8A and FIG. 8B illustrate In composition ratio and energy of the well layer for showing a problem of the another LED disclosed in Document 1;

FIG. 9 illustrates a cross sectional view of a LED in accordance with a second embodiment;

FIG. 10 illustrates a cross sectional view of a LED in accordance with a third embodiment; and

FIG. 11A and FIG. 11B illustrate In composition ratio of a well layer in a LED in accordance with a fourth embodiment.

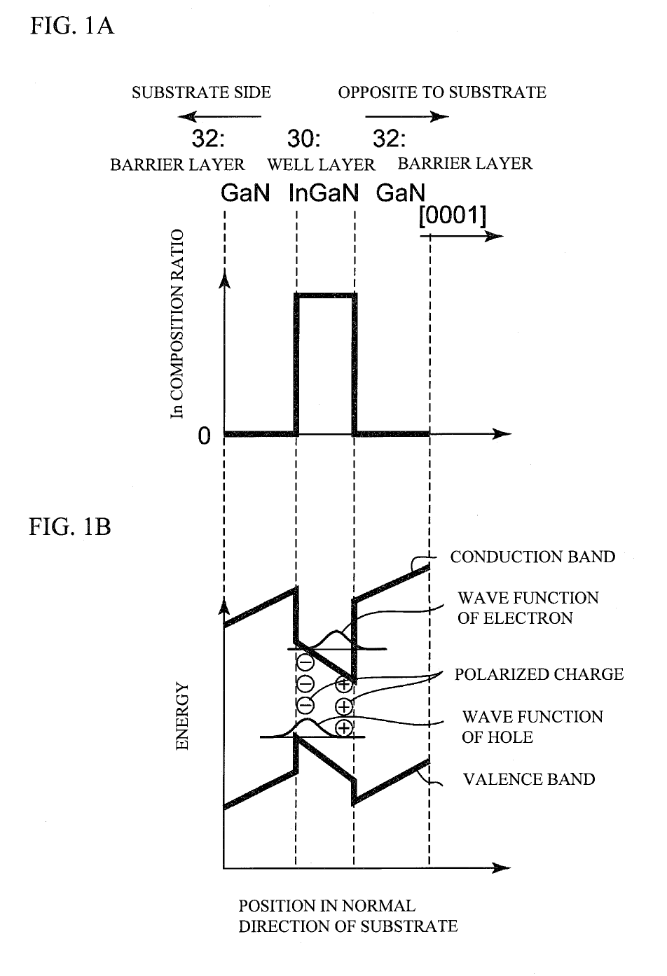

### DESCRIPTION OF THE PREFERRED EMBODIMENTS

A description will now be given of embodiments of the present invention with reference to the accompanying drawings.

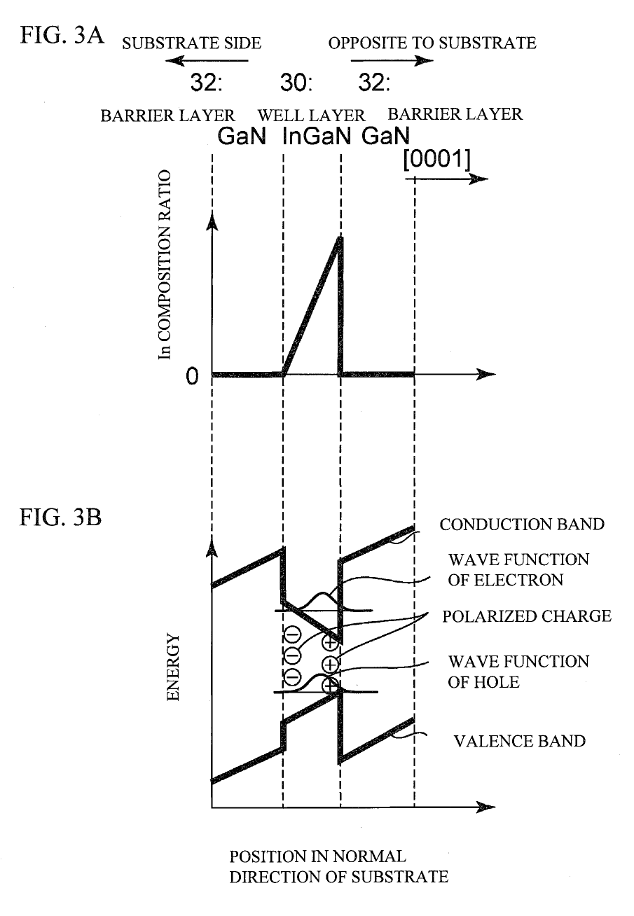

FIG. 3A and FIG. 3B illustrate In composition ratio and energy band of a GaN/InGaN-MQW active layer in accordance with the present invention. As shown in FIG. 3A and FIG. 3B, the composition of the well layer 30 is controlled so that the In composition ratio of the well layer 30 increases toward one side opposite to the substrate (a side away from the substrate). The present invention improves the light emitting efficiency by increasing the In composition ratio on the opposite side to the substrate.

### First Embodiment

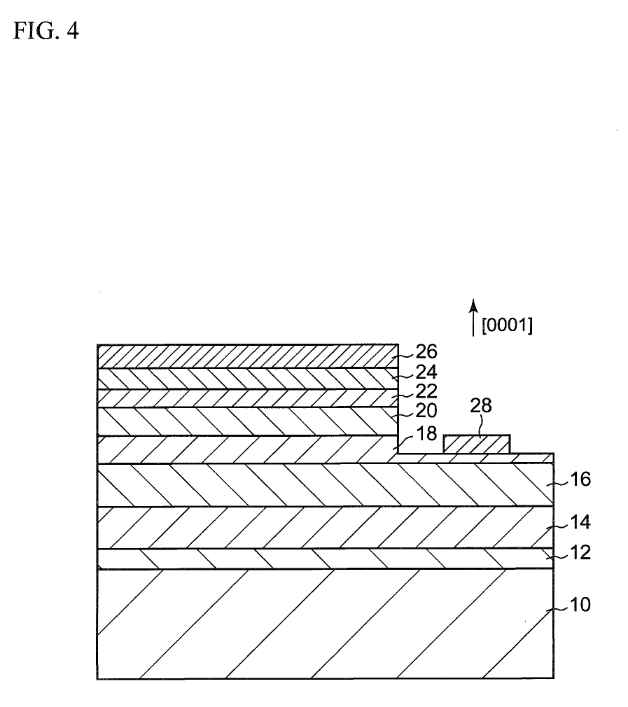

FIG. 4 illustrates a cross section view of a LED in accordance with a first embodiment. As shown in FIG. 4, there are laminated an AlN buffer layer 12, a GaN buffer layer 14, an N-type first GaN cladding layer 16, an N-type InGaN contact layer 18, an N-type second GaN cladding layer 20 (corresponding to a first conductivity type semiconductor layer), a MQW active layer 22 and a P-type GaN cladding layer 24 (corresponding to a second conductivity type semiconductor layer) on a sapphire substrate 10 in order, with MOCVD method. Each layer is formed so that a normal line direction of the substrate 10 is [0001]. A P electrode 26 is formed on the P-type GaN cladding layer 24. An N electrode 28 is formed on the N-type InGaN contact layer 18.

A growth condition of each layer is given below.

The AlN buffer layer 12 at high temperature: thickness was 0.1 μm; undoped; growth temperature was 1230 degrees C.; and carrier gas was hydrogen.

The GaN buffer layer 14: thickness was 2 μm; undoped; growth temperature was 1180 degrees C.; carrier gas was hydrogen.

The N-type first GaN cladding layer 16: thickness was 1.35 μm; Si doped; growth temperature was 1180 degrees C.; and carrier gas was hydrogen.

The N-type InGaN contact layer 18: thickness was 0.5 μm; In composition ratio was 0.5%; Si doped; growth temperature was 950 degrees C.; and carrier gas was nitrogen.

The N-type second GaN cladding layer 20: thickness was 0.15 μm; Si doped; growth temperature was 1180 degrees C.; and carrier gas was hydrogen.

The MQW active layer 22: growth temperature was 820 degrees C.; carrier gas was nitrogen; each barrier layer 32 and each well layer were laminated alternately; and the number of the well layer was five.

The GaN barrier layer 32: thickness was 9 nm.

The InGaN well layer 30: a flow rate of TMI (trimethyl indium) was 16 μmol/min; a flow rate of TMG (trimethyl gallium) was 40 μmol/min; and a flow rate of NH₃ (ammonium) was 12000 sccm.

The P-type GaN cladding layer 24: thickness was 0.2 μm, Mg doped; growth temperature was 1100 degrees C.; and carrier gas was hydrogen.

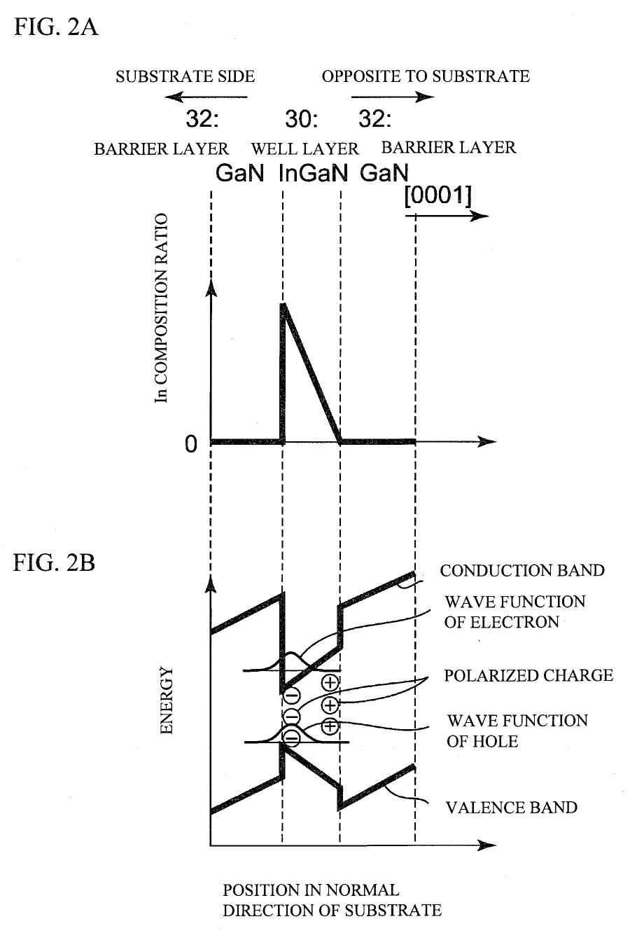

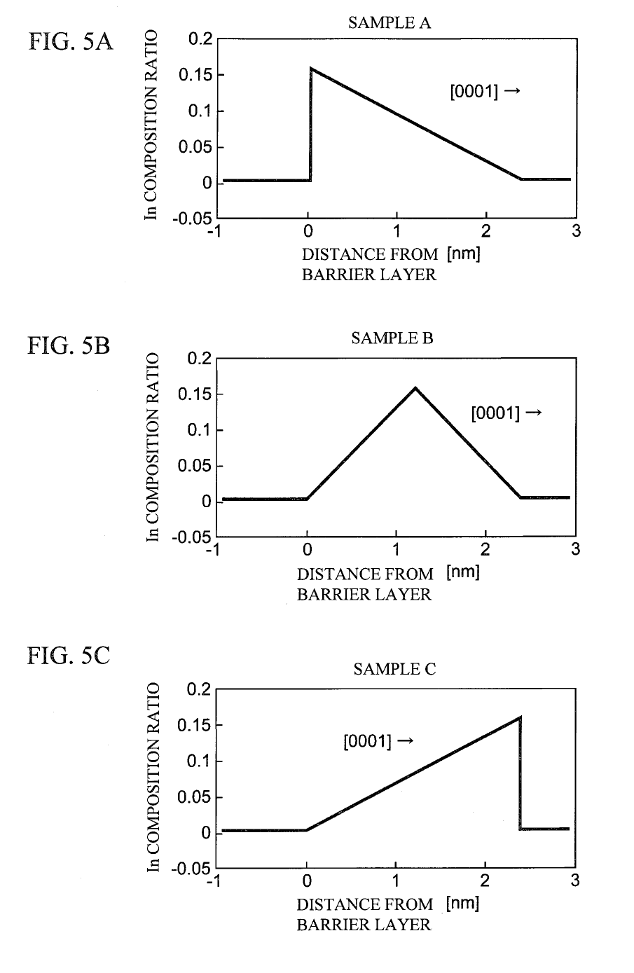

The following is a description of samples noted in the first embodiment. FIG. 5A through FIG. 5C illustrate a target composition ratio of In of the well layer 30 in a manufactured samples. The samples were manufactured so that In source flow rate of the well layer 30 was controlled to achieve the target composition ratio. As shown in FIG. 5A, a sample A had the In composition ratio of 0.16 on the substrate side and had the In composition ratio of 0 on the opposite side to the substrate. As shown in FIG. 5B, a sample had the In composition ratio of 0 on the substrate side and the opposite side to the substrate and had the In composition ratio of 0.16 in a center region of the well layer 30. As shown in FIG. 5C, a sample C had the In composition ratio of 0 on the substrate side and had the In composition ratio of 0.16 on the opposite side to the substrate. The sample A corresponds to FIG. 2A and FIG. 2B. The sample C corresponds to FIG. 3A and FIG. 3B. Each well layer 30 of the samples A through C had thickness of approximately 2.4 nm. A sample D was manufactured, although the sample D is not shown in FIG. 5A through FIG. 5C. The sample D had the In composition ratio of 0 on the substrate side and had the In composition ratio of 0.16 on the opposite side to the substrate. The thickness of the well layer 30 in the sample D was approximately 2.1 μm that was smaller than that of the sample C.

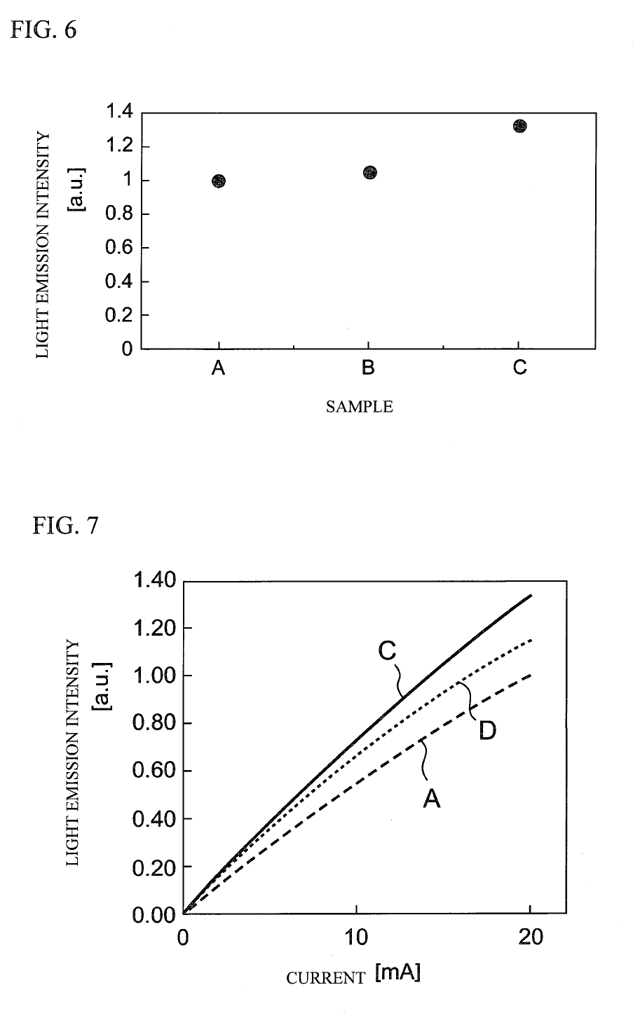

FIG. 6 illustrates light emission intensity (that is a light-emitting efficiency) of the samples A through C that is normalized by the light emission intensity of the sample A in a case where driving currents equal to each other were respectively provided to the samples A through C. There was little difference between light emission intensities of the sample A and the sample B. In contrast, the light emission intensity of the sample C was 1.3 times as large as that of the sample A.

FIG. 7 illustrates light emission intensity with respect to a current flowing between the N electrode 28 and the P electrode 26 of the samples A, B and D. The light emission intensity of the sample C was larger than that of the sample A with respect to a given current. The light emission intensity of the sample D was between those of the samples A and C. The light emission intensity is enlarged when the thickness of the well layer 30 is enlarged, according to the comparison of the samples C and D.

The light-emitting efficiency in a case where the In composition ratio of the well layer 30 was enlarged on the substrate side (the sample A) was different from that in a case where the In composition ratio of the well layer 30 was enlarged on the opposite side (the sample C). Generally, the light-emitting efficiencies should be substantially equal to each other because the electron and the hole spatially correspond to each other in a potential well, if the well layer 30 is formed in accordance with a design requirement in each case.

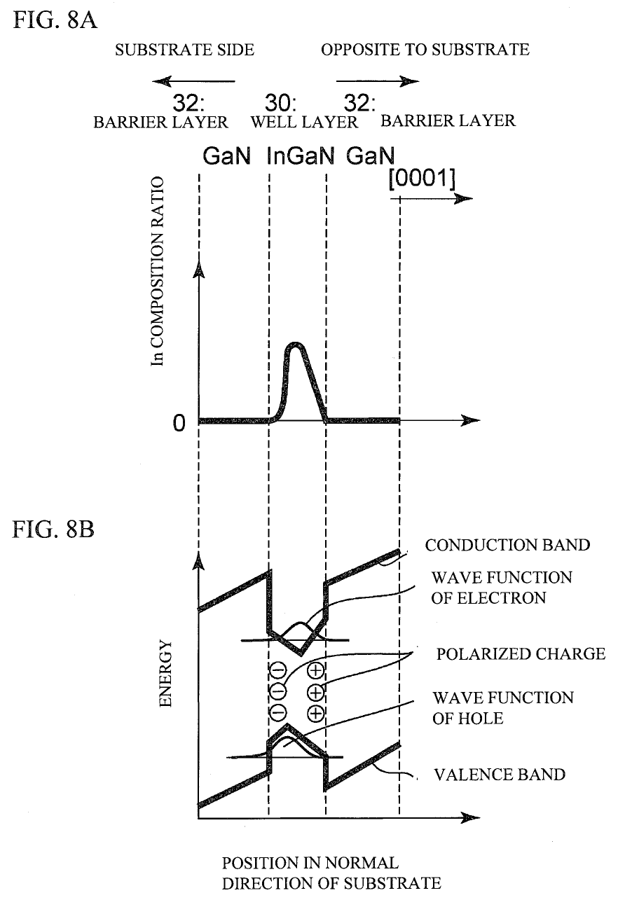

It is thought that a following phenomenon was occurred, although a reason why the light-emitting efficiency differs between the samples A and C is not obvious. In the case of the sample A, it is demanded that a peak of the In composition ratio of the well layer 30 is positioned at an interface between the well layer 30 and the barrier layer 32 on the substrate side. A growth device (for example, a MOCVD device) should be controlled so that the In source supply is maximum as soon as the growth of the well layer 30 begins. However, the amount of the In provided to a growth face does not change to the maximum instantly, in a case where the In is provided. Actually, the amount changes to the maximum after a given transient period. Therefore, the peak of the In composition ratio is actually positioned away from the interface between the well layer 30 and the barrier layer 32 on the substrate side, as shown in FIG. 8A. After that, the In composition is reduced gradually. Therefore, the In composition ratio is different from the ideal In composition ratio as shown in FIG. 2A. This results in a formation of a bottom of the conduction band and a term of the valence band in the well layer 30 away from the interface between the well layer 30 and the barrier layer 32 on the substrate side. The bottom of the conduction band and the term of the valence band may not be defined with the interface between the barrier layer 32 and the well layer 30.

On the other hand, the sample C is considered. The sample C has the well layer 30 in which the peak of the In composition ratio is positioned at the interface between the well layer 30 and the barrier layer 32 opposite to the substrate. It is not necessary that the amount of the In material changes to the maximum instantly as in the case of the sample A, because the In composition ratio has only to increase gradually (for example, increase gradually from zero) at the interface between the well layer 30 and the barrier layer 32 on the substrate side. The In composition ratio is peaked at the interface between the well layer 30 and the barrier layer 32 opposite to the substrate when the provision of the In source is stopped, if the In source is stopped. This results in a correspondence between the interface between the well layer 30 and the barrier layer 32 opposite to the substrate and the peak of the In composition ratio.

The peak of the In composition ratio is positioned at the ideal position because of the structure in which the In composition ratio indicates the maximum at the interface between the well layer 30 and the barrier layer 32 opposite to the substrate. This results in a definition of the positions of the bottom of the conduction band and the term of the valence band with the interface between the barrier layer 32 and the well layer 30. Therefore, the spatial separation between the electron and the hole is restrained. This results in a difference between the light-emitting efficiencies of the samples A and C.

It is expected to restrain that impurity left on an inner wall of the growth device is introduced into the well layer 30 and the light-emitting efficiency is reduced, if it is designed that the In composition ratio is peaked at the interface between the well layer 30 and the barrier layer 32 opposite to the substrate as in the case of the sample C. That is, the impurity left on the inner wall of the growth device tends to be introduced when the In source changes instantly as in the case of the sample A, although the impurity causes the reduction of the light-emitting efficiency when introduced during the growth of the MQW active layer. Therefore, the impurity is introduced into the well layer 30 in the case of the sample A, and the impurity is introduced into the barrier layer 32 opposite to the substrate in the case of the sample C, although the impurity is introduced in any case of the samples A, B and C.

In the well layer 30, the electron is recombined with the hole in a region where there is relatively less impurity caused by the inner wall of the growth device, if a well layer structure in which the In composition ratio is peaked at the interface between the well layer 30 and the barrier layer 32 opposite to the substrate is adopted as in the case of the sample C. It is therefore thought that the light-emitting efficiency is more improved than the sample A. The present invention may be applied to another composition modulation of another element other than In, although the In composition modulation is noted as an example of the composition modulation of the well layer 30 in the above-mentioned embodiments.

In the first embodiment, a main face of the MQW active layer 22 is (0001) face. That is, the normal line direction of the substrate is [0001] direction (the c-axis direction). Flatness of the well layer 30 and the barrier layer 32 is improved if a GaN-based semiconductor layer composed of the well layer 30 and the barrier layer 32 is grown in the [0001] direction. The piezo charge is generated because of the piezo polarization caused by the difference between the a-axis lattice constants of the barrier layer 32 and the well layer 30. Therefore, negative charge is generated on the substrate side of the well layer 30, and positive charge is generated on the opposite side of the well layer 30, as shown in FIG. 3B. However, the band gap opposite to the substrate is lower than the band gap on the substrate side. That is, the composition of the well layer 30 is controlled so that the band gap indicates the minimum value at the interface between the barrier layer 32 opposite to the substrate and the well layer 30. This results in restraint of the generation of the piezo polarization and the spatial separation between the electron and the hole. And the light-emitting efficiency is increased.

The first embodiment shows a case where the main face of the MQW active layer 22 (the barrier layer 32 and the well layer 30) is the (0001) face. The negative polarized charge is generated on the substrate side of the well layer 30 and the positive polarized charge is generated on the opposite side of the well layer 30, because the piezo polarization tends to be generated the most in a case where the normal line direction of the main face of the MQW active layer 22 is the [0001] direction. With the present invention, it is therefore possible to restrain the spatial separation between the electron and the hole. For example, a (11-22) face may be used as the main face of the MQW active layer 22.

The first embodiment shows a case where InGaN is an example of the well layer 30. Even if the well layer 30 is made of other than InGaN, Group III element is difficult to be introduced as well as In because of the instant change of the lattice constant if the well layer 30 is made of GaN-based semiconductor. The energy band gap has only to be smaller than the barrier layer 32. Any crystal or any mixed crystal of GaN, AlN and InN may be used. That is, the barrier layer 32 and the well layer 30 may be AlₐIn_{b}Ga_{1-a-b}N (0≦a≦1, 0≦b≦1) and Al_{c}In_{d}Ga_{1-c-d}N (0≦c≦1, 0≦d≦1). However, the In is difficult to be introduced at the beginning of the growth of the well layer 30 as shown in FIG. 8A, if the well layer 30 includes In. Therefore, it is effective that the present invention is applied to the case where the well layer 30 includes In. For example, the barrier layer 32 may be made of GaN and the well layer 30 may be made of InGaN, as in the case of the first embodiment. In this case, the maximum of the In composition ratio of InGaN may be 0.16. Alternatively, both of the barrier layer 32 and the well layer 30 may be made of InGaN. In this case, the In composition ratio of the barrier layer 32 may be 0.03, and the maximum of the In composition ratio of the well layer 30 may be 0.16.

The first embodiment shows the case where the substrate 10 is the sapphire substrate. However, the substrate 10 may be made of SiC (silicon carbide), Si, GaN or Ga₂O₃ (gallium oxide).

### Second Embodiment

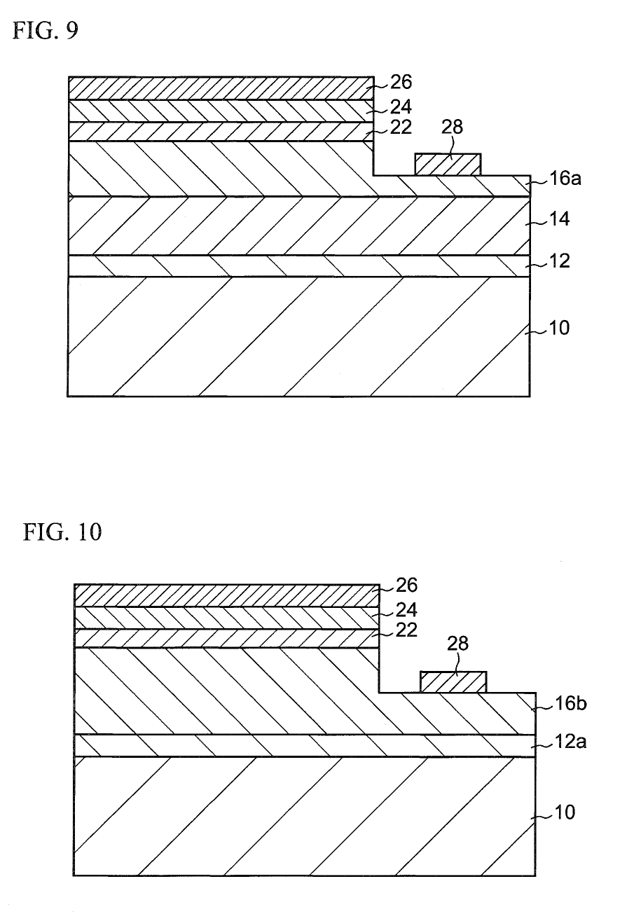

FIG. 9 illustrates a case where the contact layer is not used. As shown in FIG. 9, a semiconductor light emitting device in accordance with a second embodiment has a Si-doped N-type GaN cladding layer 16a (corresponding to the first conductivity type semiconductor layer) having thickness of 2 μm instead of the N-type first GaN cladding layer 16, the N-type InGaN contact layer 18 and the N-type second GaN cladding layer 20, being different from FIG. 5 of the first embodiment. The N electrode 28 is electrically connected to the N-type GaN cladding layer 16a. The other structure is the same as that of the first embodiment shown in FIG. 5.

The AlN buffer layer 12 grown at high temperature has crystal quality and the a-axis lattice constant of the GaN layer grown on the AlN buffer layer 12 is reduced because of the AlN buffer layer 12, in a case where the high-temperature AlN buffer layer 12 is used as in the case of the first embodiment and the second embodiment. Therefore, introduction of In is more prevented if InGaN having large a-axis lattice constant is grown as the well layer 30 in the MQW active layer 22. Consequently, the present invention is particularly effective for a case where the high-temperature AlN buffer layer 12 is provided.

The high-temperature AlN buffer layer 12 has crystal quality in a case where the growth temperature is more than 1000 degrees C., preferably in a case where the growth temperature is more than the growth temperature of the MQW active layer 22.

### Third Embodiment

A third embodiment shows a case where a low-temperature GaN buffer layer is used. As shown in FIG. 10, a low-temperature GaN buffer layer 12a is used instead of the high-temperature AlN buffer layer 12 of the first embodiment shown in FIG. 5. The growth condition of the low-temperature GaN buffer layer 12a is shown below.

The low-temperature GaN buffer layer 12a: thickness is 0.1 μm; undoped; growth temperature is 600 degrees C.; and carrier gas is hydrogen.

A Si-doped N-type GaN cladding layer 16b (corresponding to the first conductivity type semiconductor layer) having thickness of 5 μm is used instead of the GaN buffer layer 14, the N-type first GaN cladding layer 16, the N-type InGaN contact layer 18 and the N-type second GaN cladding layer 20. The other structure is the same as that of FIG. 5 in the first embodiment. The low-temperature buffer layer may be used as in the case of the third embodiment.

### Fourth Embodiment

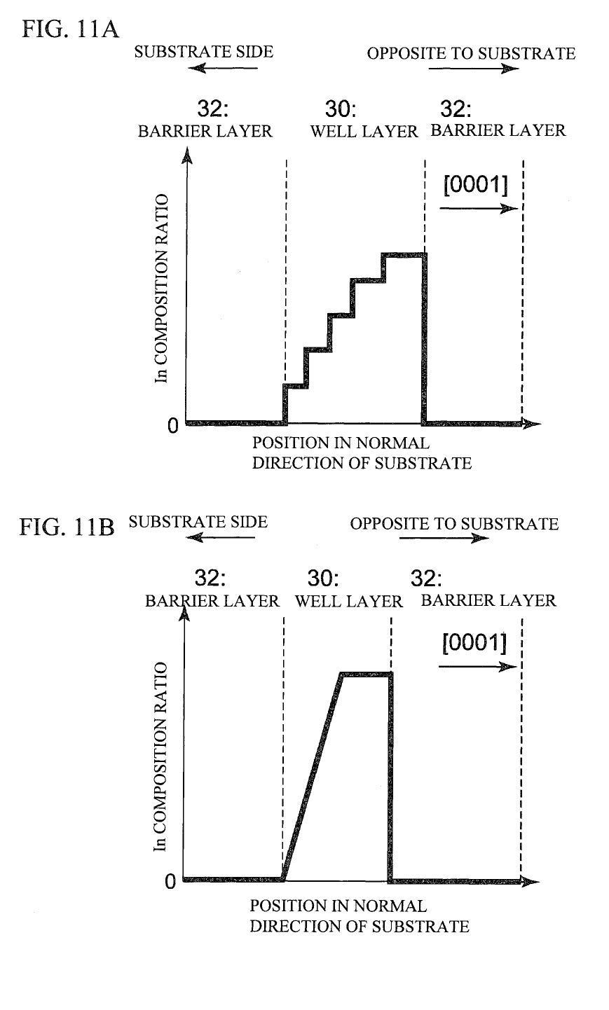

A fourth embodiment shows a case where the profile of the In composition ratio of the well layer 30 is different from the other embodiments. FIG. 11A and FIG. 11B illustrate the In composition ratio of the well layer 30 of a LED in accordance with the fourth embodiment. As shown in FIG. 11A, the In composition ratio of the well layer 30 may be shifted stepwise. And, as shown in FIG. 11B, a part of the In composition ratio of the well layer 30 may be shifted gradually, and the rest of the In composition ratio may be constant.

The band gap of the well layer 30 may be shifted gradually from the substrate side to the opposite side, as in the case of the first embodiment. The band gap (a composition modulation) may be shifted gradually or stepwise at least in a part of the well layer 30 from the substrate 10 side to the opposite side, as in the case of the fourth embodiment. The wave function of the electron or the hole is peaked at the interface between the barrier layer 32 opposite to the substrate and the well layer 30, and the peak of the wave function of the electron or the hole is not introduced toward the interface between the barrier layer 32 on the substrate side and the well layer 30, if a range where the In composition ratio is constant is in a desired range. Therefore, the spatial separation of the wave functions of the electron and the hole is restrained.

The first conductivity type is N-type and the second conductivity type is P-type in the above-mentioned embodiments. However, the first conductivity type may be P-type and the second conductivity type may be N-type.

The present invention is not limited to the specifically disclosed embodiments, but include other embodiments and variations without departing from the scope of the present invention.

The present application is based on Japanese Patent Application No. 2007-132193 filed on May 17, 2007, the entire disclosure of which is hereby incorporated by reference.

What is claimed is:

1. A semiconductor light emitting device comprising:
a substrate; and
a quantum well active layer that has a plurality of barrier layers made of GaN-based semiconductor and a well layer made of GaN-based semiconductor sandwiched between the barrier layers and has polarized charge between the barrier layer and the well layer caused by piezo polarization,
the well layer having a composition modulation so that a band gap is minimum at an interface between the well layer and one of the barrier layers more far from the substrate than the other.

2. The semiconductor light emitting device as claimed in claim 1, wherein a main face of the barrier layer and the well layer is (0001) face or (11-22) face.

3. The semiconductor light emitting device as claimed in claim 1, wherein the composition modulation of the well layer is that of In.

4. The semiconductor light emitting device as claimed in claim 1, wherein the composition modulation is gradual modulation or stepwise modulation.

5. The semiconductor light emitting device as claimed in claim 1, wherein the barrier layer is made of AlₐIn_{b}Ga_{1-a-b}N (0≦a≦1, 0≦b≦1) and the well layer is made of Al_{c}In_{d}Ga_{1-c-d}N (0≦c≦1, 0≦d≦1).

6. The semiconductor light emitting device as claimed in claim 1, wherein the substrate is made of SiC, Si, sapphire, GaN or Ga₂O₃.
